(19) United States
(12) Patent Application Publication
(10) Pub. No.: US 2007/0279060 A1
(43) Pub. Date: Dec. 6, 2007

(54) Dynamic Shimset Calibration for Bo Offset

(75) Inventors: Wayne R. Dannels, Mentor, OH (US); David L. Foxall, Mentor, OH (US); Gordon D. DeMeester, Wickliffe, OH (US)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 10/598,867

(22) PCT Filed: Feb. 17, 2005
(86) PCT No.: PCT/IB05/50607

§ 371 Date: May 29, 2007

Related U.S. Application Data
(60) Provisional application No. 60/554,081, filed on Mar. 17, 2004.

(51) Int. Cl. G01R 33/38

(52) U.S. Cl. 324/320

(57) ABSTRACT

A magnetic resonance imaging scanner includes a main magnet (20) generating a main B₀ magnetic field, one or more shim coils (60) selectively shimming the main B₀ magnetic field at selected shim currents, and a processor (70) executing a process including determining a magnitude shift of the main B₀ magnetic field responsive to the selective shimming and performing a correction during the energizing to correct for the determined magnitude shift of the main B₀ magnetic field. The performed correction includes one of (i) selectively energizing a D.C. shim coil (82) to counteract the determined magnitude shift of the main B₀ magnetic field and (ii) computing a magnetic resonance frequency corresponding to the main B₀ magnetic field including the determined magnitude shift and tuning a radio frequency transceiver (44, 46) to the computed magnetic resonance frequency.

The following relates to the magnetic resonance arts. It finds particular application in magnetic resonance imaging, and will be described with particular reference thereto. However, it also finds application in magnetic resonance spectroscopy and other techniques that benefit from a main B₀ magnetic field of precisely known magnitude.

In magnetic resonance imaging, a temporally constant main B₀ magnetic field is produced that is spatially uniform at least over a field of view. Achieving sufficient uniformity for larger main B₀ magnetic field strengths, such as 3 Tesla or higher, can be difficult. Non-uniformities in the main B₀ magnetic field can produce various types of image artifacts. For example, in echo planar imaging, main field non-uniformities can lead to pixel shifting in the reconstructed images. Design tradeoffs to achieve hardware cost reduction, greater compactness of scanners, more open access for the subject or patient, and so forth also may contribute to magnetic field non-uniformities

Main B₀ magnetic field uniformity can be improved using active shimming, in which dedicated shim coils produce a supplementary or shim magnetic fields that compensate for non-uniformities of the magnetic field produced by the main magnet. The main magnet is usually superconducting, while the shim coils are usually resistive coils. In one embodiment, each shim coil produces a magnetic field having a spatial distribution that is functionally orthogonal to the magnetic fields produced by the other shim coils. For example, each shim coil can produce a magnetic field having a spatial distribution corresponding to Legendre polynomials or spherical harmonic components.

To calibrate the shim currents, a magnetic field probe or other device, or a dedicated magnetic resonance sequence executed by the scanner, is used to measure the spatial distribution of the main B₀ magnetic field without the shim coils energized. The spatial distribution is decomposed into orthogonal spatial components such as spherical harmonic terms. Orthogonal terms of the unshimmed magnetic field which should be increased are supplemented using corresponding shim coils, while orthogonal terms which should be decreased are partially canceled by energizing corresponding shim coils to produce opposing shim fields.

Typically, the shim currents are calibrated infrequently, such as when the magnetic resonance scanner is installed, after major maintenance, or the like. The stored shim current calibration values are applied during magnetic resonance imaging sessions to improve main B₀ field uniformity.

At higher main B₀ magnetic fields, such as at about 3 Tesla or higher, magnetic properties of the imaged subject, such as the magnetic susceptibility, increasingly distort the main B₀ magnetic field. These distortions are generally imaging subject-dependent, and may also depend upon the positioning of the imaging subject and the region of interest of the subject which is being imaged. In such situations, it becomes advantageous to perform dynamic shimming, in which shim coil currents are adjusted for each specific imaging subject, and perhaps are adjusted during an imaging session as the imaged region shifts.

To perform shimming that accounts for distortion caused by the imaging subject, the main B₀ magnetic field is measured with the imaging subject in situ using magnetic field sensors disposed in the magnet or a magnetic field mapping pulse sequence executed by the magnetic resonance imaging scanner. The mapped spatial distribution of the main B₀ magnetic field is decomposed into orthogonal components and suitable corrective shim coil magnetic fields are determined and applied.

Shim coils are designed to adjust the main B₀ magnetic field which is directed along a selected main field axis. In typical horizontal bore magnets, this axis typically lies along the bore axis and is designated as the z-axis; however, vertical magnets or other geometric configurations can also be employed. Hence, the shim coils are designed principally to produce a magnetic field component parallel to the main field axis (for example parallel to the z-axis for a horizontal bore magnet) to enable spatially selective enhancement or partial cancellation of the main B₀ magnetic field. However, the shim coils also produce some components transverse to the main field axis (for example perpendicular to the z-axis for a horizontal bore magnet).

These transverse shim magnetic field components contribute to a shift in the magnitude of the shimmed main B₀ magnetic field, and hence contribute to a shift in the resonance frequency. The shimming-induced magnetic field magnitude shift depends upon the magnitude of the shim currents applied. Such magnetic field magnitude shifts are problematic for imaging techniques that depend on having a precise main field. For example, in echo planar imaging, compact spiral k-space trajectory imaging, chemical shift selective excitation, and some other techniques, the magnitude shift of the main field due to shimming can produce pixel shifting or other deleterious image artifacts.

The present invention contemplates an improved apparatus and method that overcomes the aforementioned limitations and others.

According to one aspect, a magnetic resonance imaging method is provided. A magnitude shift of a main B₀ magnetic field responsive to energizing one or more shim coils at selected shim currents is determined. The one or more shim coils are energized at the selected shim currents. A correction is performed during the energizing to correct for the determined magnitude shift of the main B₀ magnetic field.

According to another aspect, a magnetic resonance imaging apparatus is disclosed. A means is provided for generating a main B₀ magnetic field. One or more shim coils shim the main B₀ magnetic field. A means is provided for determining a magnitude shift of the main B₀ magnetic field responsive to energizing the one or more shim coils at selected shim currents. A means is provided for energizing the one or more shim coils at the selected shim currents. A means is provided for performing a correction during the energizing to correct for determined magnitude shift of the main B₀ magnetic field.

According to yet another aspect, a magnetic resonance imaging scanner is disclosed. A main magnet generates a main B₀ magnetic field. One or more shim coils selectively shim the main B₀ magnetic field at selected shim currents. A processor executes a process including determining a magnitude shift of the main B₀ magnetic field responsive to the selective shimming.

One advantage resides in facilitating patient-specific shimming.

Another advantage resides in facilitating dynamic shimming during imaging.

Yet another advantage resides in improved image quality due to a close agreement between the shimmed main B₀ magnetic field magnitude and tuning of the radio frequency transceiver.

Numerous additional advantages and benefits will become apparent to those of ordinary skill in the art upon reading the following detailed description of the preferred embodiments.

The invention may take form in various components and arrangements of components, and in various process operations and arrangements of process operations. The drawings are only for the purpose of illustrating preferred embodiments and are not to be construed as limiting the invention.

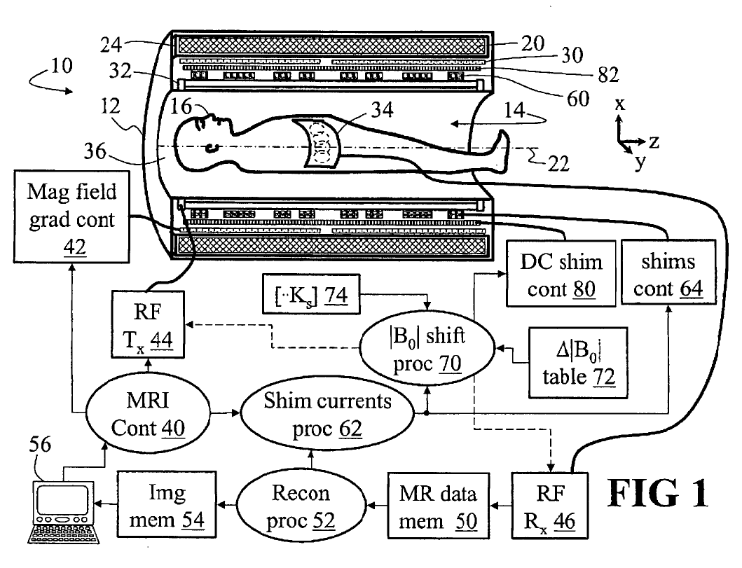

FIG. 1 diagrammatically shows a magnetic resonance imaging system implementing patient-specific and/or dynamic main B₀ magnetic field shimming.

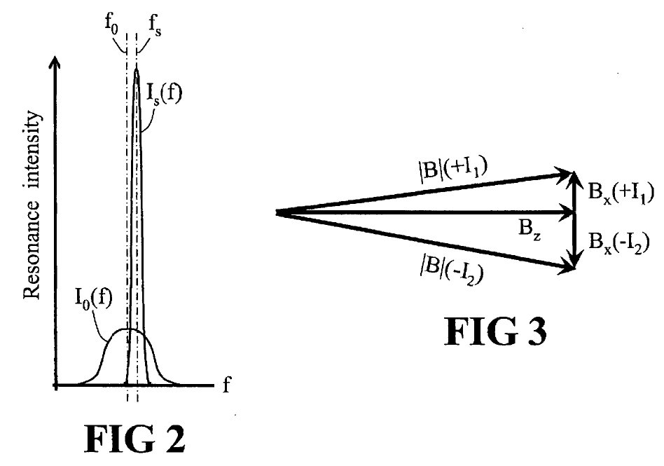

FIG. 2 diagrammatically plots the typical effect of increased shimming on the magnetic resonance frequency distribution in the main B₀ magnetic field.

FIG. 3 diagrammatically shows vector computation of the magnitude shift of the main B₀ magnetic field magnitude due to shimming.

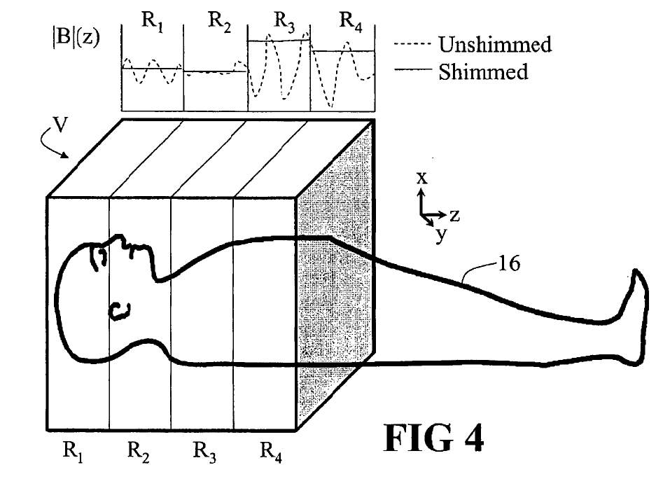

FIG. 4 diagrammatically shows dynamic shimming implemented by separately shimming four imaging regions of the volume of interest.

With reference to FIG. 1, a magnetic resonance imaging scanner 10 includes a housing 12 defining a generally cylindrical scanner bore 14 inside of which an associated imaging subject 16 is disposed. Main magnetic field coils 20 are disposed inside the housing 12, and produce a main B₀ magnetic field parallel to a central axis 22 of the scanner bore 14. In FIG. 1, the direction of the main B₀ magnetic field is parallel to the z-axis of the reference x-y-z Cartesian coordinate system. Main magnetic field coils 20 are typically superconducting coils disposed inside cryoshrouding 24, although resistive main magnets can also be used.

The housing 12 also houses or supports magnetic field gradient coils 30 for selectively producing magnetic field gradients parallel to the central axis 22 of the bore 14, along in-plane directions transverse to the central axis 22, or along other selected directions. The housing 12 further houses or supports a radio frequency body coil 32 for selectively exciting and/or detecting magnetic resonances. An optional coil array 34 disposed inside the bore 14 includes a plurality of coils, specifically four coils in the illustrated example coil array 34, although other numbers of coils can be used. The coil array 34 can be used as a phased array of receivers for parallel imaging, as a sensitivity encoding (SENSE) coil for SENSE imaging, or the like. In one embodiment, the coil array 34 is an array of surface coils disposed close to the imaging subject 16. The housing 12 typically includes a cosmetic inner liner 36 defining the scanner bore 14.

The coil array 34 can be used for receiving magnetic resonances that are excited by the whole body coil 32, or the magnetic resonances can be both excited and received by a single coil, such as by the whole body coil 32. It will be appreciated that if one of the coils 32, 34 is used for both transmitting and receiving, then the other one of the coils 32, 34 is optionally omitted.

The main magnetic field coils 20 produce a main B₀ magnetic field. A magnetic resonance imaging controller 40 operates magnetic field gradient controllers 42 to selectively energize the magnetic field gradient coils 30, and operates a radio frequency transmitter 44 coupled to the radio frequency coil 32 as shown, or coupled to the coils array 34, to selectively energize the radio frequency coil or coil array 32, 34. By selectively operating the magnetic field gradient coils 30 and the radio frequency coil 32 or coil array 34 magnetic resonance is generated and spatially encoded in at least a portion of a region of interest of the imaging subject 16. By applying selected magnetic field gradients via the gradient coils 30, a selected k-space trajectory is traversed, such as a Cartesian trajectory, a plurality of radial trajectories, or a spiral trajectory. Alternatively, imaging data can be acquired as projections along selected magnetic field gradient directions. During imaging data acquisition, a radio frequency receiver 46 coupled to the coils array 34, as shown, or coupled to the whole body coil 32, acquires magnetic resonance samples that are stored in a magnetic resonance data memory 50.

The imaging data are reconstructed by a reconstruction processor 52 into an image representation. In the case of k-space sampling data, a Fourier transform-based reconstruction algorithm can be employed. Other reconstruction algorithms, such as a filtered backprojection-based reconstruction, can also be used depending upon the format of the acquired magnetic resonance imaging data. For SENSE imaging data, the reconstruction processor 52 reconstructs folded images from the imaging data acquired by each coil and combines the folded images along with coil sensitivity parameters to produce an unfolded reconstructed image.

The reconstructed image generated by the reconstruction processor 52 is stored in an image memory 54, and can be displayed on a user interface 56, stored in non-volatile memory, transmitted over a local intranet or the Internet, viewed, stored, manipulated, or so forth. The user interface 56 can also enable a radiologist, technician, or other operator of the magnetic resonance imaging scanner 10 to communicate with the magnetic resonance imaging controller 40 to select, modify, and execute magnetic resonance imaging sequences.

The main magnetic field coils 20 generate the main B₀ magnetic field, preferably at about 3 Tesla or higher, which is substantially uniform in the imaging volume of the bore 14. However, some non-uniformity may be present or may develop over time due to mechanical or electronic drift of components of the scanner 10. The amount of image distortion caused by such non-uniformity may depend upon the location of imaging within the bore 14. Moreover, when the associated imaging subject 16 is inserted into the bore 14, the magnetic properties of the imaging subject can distort the main B₀ magnetic field.

To improve the uniformity of the main B₀ magnetic field, one or more shim coils 60 housed or supported by the housing 12 provide active shimming of the main B₀ magnetic field. In one embodiment, each shim coil produces a shimming magnetic field having a spatial distribution that is functionally orthogonal to the magnetic fields produced by the other shim coils. For example, each shim coil can produce a magnetic field having a spatial distribution corresponding to a spherical harmonic component. By selectively energizing the various shim coils 60 at selected shim currents, non-uniformities of the main B₀ magnetic field are reduced.

Ideally, each shim coil produces a magnetic field distribution within the bore 14 that includes only B_{z} components, that is, magnetic fields directed parallel to the main B₀ magnetic field parallel to the z-direction, with no transverse Bₓ or B_{y} components. The B_{z} components are selected to enhance or partially cancel the main B₀ magnetic field produced by the main magnetic field coils 20 to correct for inherent non-uniformities, for distortion caused by the imaging subject 16, or the like. Specifically, a shim currents processor 62 determines appropriate shim currents for one or more of the shim coils 60 to reduce non-uniformity of the main B₀ magnetic field. The shim currents processor 62 selects appropriate shim currents based on known configurations of the shim coils 60 and based on information on the magnetic field non-uniformity that needs to be corrected. Non-uniformity of the main B₀ magnetic field can be determined in various ways, such as by acquiring a magnetic field map using a magnetic field mapping magnetic resonance sequence executed by the scanner 10, by reading optional magnetic field sensors (not shown) disposed in the bore 14, by performing a priori computation of the expected magnetic field distortion produced by introduction of the imaging subject 16, or so forth. Magnetic field measurement sequences may be intermixed with the imaging sequence to check the main B₀ magnetic field magnitude periodically, e.g. after each slice. The shim currents processor 62 controls a shims controller 64 to energize one or more of the shim coils 60 at the selected shim currents.

Although it would be desirable for each shim coil to produce a magnetic field distribution within the bore 14 that includes only B_{z} components, because the magnetic flux must follow a closed loop, the shim coils 60 typically also produce at least some residual transverse magnetic field components, such as Bₓ and/or B_{y} components, in at least a portion of the bore 14. A consequence of these transverse magnetic field components is that while the shimming reduces spatial non-uniformity of the main B₀ magnetic field, the average or mean magnitude |B| of the main B₀ magnetic field changes, and usually increases, with increased shimming.

The resonance frequency fᵣₑₛ at a given point in space is given by:
fᵣₑₛ=γ|B(x,y,z)| (1),
where |B(x,y,z)| is the magnitude of the magnetic field at position (x,y,z) and γ is the gyrometric ratio for the excited nuclear magnetic resonance. The magnitude |B(x,y,z)| depends upon the total field, not just the B_{z} component. Using the Cartesian coordinate system designated in FIG. 1:
|B(x,y,z)|²=[Bₓ(x,y,z)]²+[B_{y}(x,y,z)]²+[B_{z}(x,y,z)]² (2).
As an example, ¹H proton nuclei have a gyrometric ratio γ=42.58 MHz/Tesla, so at |B(x,y,z)|=3.0 Tesla the resonance frequency is approximately fᵣₑₛ=128 MHz. Equation (1) indicates that the frequency distribution of magnetic resonance intensity thus corresponds to the distribution of the magnitude of the magnetic field in the imaging volume.

With reference to FIG. 2, which plots the distribution of magnetic resonance intensity as a function of frequency, the observed effect of shimming on the magnitude of the main B₀ magnetic field is illustrated. In FIG. 2, the unshimmed magnetic resonance intensity distribution as a function of frequency, denoted I₀(f), is relatively broad and centered at an unshimmed center frequency f₀. The breadth of the unshimmed magnetic resonance intensity distribution I₀(f) reflects a substantial spatial non-uniformity of the unshimmed main B₀ magnetic field in the bore 14. As shimming is applied using shimming currents selected to reduce the field non-uniformity, the magnetic resonance intensity distribution becomes narrower, reflecting improved spatial uniformity. In FIG. 2, a shimmed, substantially spatially uniform magnetic field provides a narrow magnetic resonance intensity distribution denoted Iₛ(f).

In addition to being substantially narrowed, however, the shimmed magnetic resonance intensity distribution Iₛ(f) is also shifted toward higher frequency, and has a center frequency fₛ>f₀. For applications in which the shimming may be adjusted relatively frequently, this shift in the resonance frequency can be problematic and can lead to image artifacts. In applications where dynamic shimming is performed during imaging, such frequency shifting occurs during the imaging.

With reference to FIG. 3, a vector computation of the magnitude shift of the main B₀ magnetic field magnitude due to shimming is drawn. The desired shimmed magnetic field has a component in the z-direction of magnitude B_{z}. If at a given position (x,y,z) the magnetic field produced by the main magnetic field coils 20 is less than B_{z}, then the shimming preferably enhances that field to the value B_{z}. Similarly, if the magnetic field produced by the main magnetic field coils 20 is greater than B_{z}, then the shimming preferably partially cancels that field to match the value B_{z}.

Thus, the shimmed magnetic field has a substantially spatially uniform B_{z} component indicated in FIG. 3 throughout the bore 14. However, any additional, undesired transverse magnetic field components produced by the shimming, such as the illustrated component Bₓ(+I₁) or the illustrated component Bₓ(−I₂), both oriented along the x-direction, are not accounted for in determining the desired shim current. Thus, as illustrated in FIG. 3, if a shim current +I₁ is required to produce the B_{z} field, and this shim current +I₁ produces an additional undesired transverse component B_{z}(+I₂), then the total field at the position (x,y,z) is |B|(+I₁)=(B_{z}²+[Bₓ(+I₁)]²)^{0.5} which is greater than the desired magnitude B_{z}. Similarly, if a shim current −I₂ is required to produce the B_{z} field, and this shim current −I₂ produces an additional undesired transverse component Bₓ(−I₂), then the total field at the position (x,y,z) is |B|(−I₂)=(B_{z}²+[Bₓ(−I₂)]²)^{0.5} which is also greater than the desired magnitude B_{z}. Indeed, it will be appreciated that any transverse component, regardless of its positive or negative sense or its transverse orientation, will tend to increase the magnitude of the shimmed magnetic field. These effects of undesired transverse components are typically small, since the shim components are typically smaller than the main B₀ component, and the nature of the vector magnitude operation depends only weakly on spatially orthogonal components which are smaller than the largest component. However, the requirement that the magnetic field flux lines form a closed loop typically prevents the transverse components from being identically zero everywhere within the bore 14.

These transverse magnetic fields, and their contribution to the total vector magnitude magnetic field are referred to here as Maxwell terms. In some literature, they are also sometimes referred to as Maxwell fields or concomitant fields.

With reference returning to FIG. 1, a magnitude shift processor 70 determines the magnitude shift of the main B₀ magnetic field expected to occur responsive to energizing one or more of the shim coils 60 at the shim currents selected by the shim currents processor 62. The magnitude shift processor 70 performs this computation before the shim coils 60 are actually energized, to provide an a priori prediction of the magnitude shift. The a priori computation can be performed by accessing a previously determined magnitude shift calibration table 72 that stores magnitudes shifts previously measured for various shim currents and combinations of shim currents. For example, the magnetic resonance intensity distribution can be measured as a function of frequency for various shim currents and combinations of shim currents to determine shifted frequencies fₛ for the various shim currents and current combinations as illustrated in FIG. 2. Based on Equation (1), the magnitude shift Δ|B₀| of the main B₀ magnetic field can be computed as:
Δ|B₀|=|B₀|_{shimmed}−|B₀|_{unshimmed}=(f_{shimmed}−f_{unshimmed})/γ (3),
where γ is again the gyrometric ratio for the measured nuclear magnetic resonances. While this empirical approach is straightforward, it generally requires measuring a large number of combinations of shim currents. Moreover, if the selected combination of shim currents is not included in the calibration table 72, potentially computationally intensive numerical interpolation is typically employed.

In another approach, magnitude shift of the main B₀ magnetic field is estimated using Maxwell terms. This approach recognizes that since the shim coils 60 are intended to produce magnetic fields oriented in the z-direction, the inequality B_{z}>>Bₓ, B_{y} typically holds. That is, the field component along the z-direction is typically much larger than the magnetic field components transverse to the z-direction. Under this condition, the magnitude shift Δ|B₀| can be represented as:
Δ|B₀|≅[¹Kₛ][Iₛ]+[²Kₛ][Iₛ²]+[⁴Kₛ][Iₛ⁴]+ . . . +[²ⁿKₛ][Iₛ²ⁿ] (4),
where [Iₛ] is a vector of shim currents applied to the shims 60. A zero element of the vector [Iₛ] indicates that the corresponding shim is not energized and thus does not contribute to the magnitude shift Δ|B₀|. The coefficients vector [¹Kₛ] is a zeroeth order coefficients vector of calibrated coefficients for the shims 60, and describes the direct B₀ term created by each of the shims 60. The coefficients vector [²Kₛ] is a first order Maxwell term coefficients vector of calibrated coefficients for the shim coils 60 that describes the first Maxwell term contribution created by each of the shim coils 60. The vector [Iₛ²] is a vector containing the shim current-squared values of shim currents applied to the shims 60. Again, a zero element in the vector [Iₛ²] indicates that the corresponding shim is not energized and thus does not contribute to the magnitude shift Δ|B₀|. Similarly, the coefficients vectors [⁴Kₛ] . . . [²ⁿKₛ] represent the 2^{nd} through nth Maxwell term coefficients, and the vectors [Iₛ⁴] . . . [Iₛ²ⁿ] represent vectors of the shim current values raised to the indicated powers.

The Maxwell coefficients vectors [^{••}Kₛ] are stored in a Maxwell coefficients vectors memory 74. In one embodiment, these coefficients are calibrated by measuring the magnetic field shift Δ|B₀| with each shim energized separately at one or a few shim current levels. The elements of the Maxwell coefficients vectors [^{••}Kₛ] for that shim coil are calibrated by optimizing the coefficients for that shim coil using Equation (4) with the [Iₛⁿ] vectors having zero elements except for elements corresponding to the energized shim. This calibration assumes that the magnitude shifts of the individually operated shim coils additively combine when two or more of the shim coils 60 are operated together, which is a convenient simplifying assumption.

Advantageously, once the Maxwell coefficients [^{••}Kₛ] are calibrated for the shim coils 60, the magnitude shift of the main B₀ magnetic field can be computed a priori for substantially any combination of selected shim currents, even combinations other than those used in the calibration, by evaluating Equation (4) using the selected shim currents as input values. The empirical functional relationship is provided in Equation (4) is a continuous function with respect to the shim currents, as compared with the discrete values typically stored in the calibration table 72, and so potentially computationally intensive numerical interpolation is generally not employed.

Instead of empirically calibrating the Maxwell coefficients [^{••}Kₛ], these coefficients can be computed from first principles based on the geometric configurations of the shim coils 60. Such first principles computations can be performed, for example, using finite element modeling of the coil geometries for various simulated shim currents and fitting the coefficients to the simulation results.

The magnitude shift Δ|B₀| of the main B₀ magnetic field computed by the magnitude shift processor 70 is used to perform a correction during the energizing of the selected one or more of the shim coils 60 to correct for the determined magnitude shift of the main B₀ magnetic field. In one embodiment, the magnitude shift Δ|B₀| computed by the magnitude shift processor 70 is compensated by operating a D.C. shim controller 80 to energize a D.C. shim coil 82. The D.C. shim coil 82 is a zero order shim coil that when energized produces a spatially uniform magnetic field in the bore 14. The D.C. shim controller 80 energizes the D.C. shim 82 at a shim current selected to oppose and substantially cancel the magnitude shift Δ|B₀| (assuming a positive magnitude shift). The D.C. shim 82 cancels the positive magnitude shift Δ|B₀| to maintain the main B₀ magnetic field at a constant value even when one or more of the shims 60 are operating.

In another embodiment, the magnitude shift processor 70 outputs a magnetic resonance frequency shift Δfᵣₑₛ equivalent to the magnitude shift Δ|B₀| of the main B₀ magnetic field. As shown by Equation (1), the magnetic resonance frequency shift Δfᵣₑₛ is equal to the magnitude shift Δ|B₀| except for the scaling gyrometric ratio factor γ. The magnetic resonance frequency shift Δfᵣₑₛ output by the magnitude shift processor 70 is used as control signals (indicated by dashed connecting arrows in FIG. 1) to control the radio frequency transceiver 44, 46 including the radio frequency transmitter 44 and the radio frequency receiver 46 to ensure that they are operating at the magnetic resonance frequency corresponding to the main B₀ magnetic field including the magnitude shift Δ|B₀|. In other words, with reference to FIG. 2 the center frequency of the transmitter 44 is tuned to the shimmed frequency fₛ. An analogous adjustment can be made at the receiver 46.

Any of the above-described magnitude shift correction embodiments or their equivalents can be employed to facilitate adjusting the shimming on a relatively frequent basis. For example, shimming can be adjusted for each patient, to account for different magnetic susceptibility properties of each patient. Moreover, any of the described magnitude shift correction embodiments or their equivalents facilitate dynamic shimming during imaging, in which the shimming is adjusted on a regional, per-slice, or other basis during the imaging session of a single patient.

With reference to FIG. 4, an imaging volume V encompasses the head and torso of the imaging subject 16. The unshimmed main B₀ magnetic field is distorted in a spatially non-uniform fashion across the imaging volume V by the imaging subject 16. In FIG. 4, this distortion is diagrammatically represented by plotting the unshimmed average main B₀ magnetic field |B(z)|, averaged over each axial slice, as a function of axial slice position in the z-direction. While the variation in the z-direction is plotted, it will be recognized that the main B₀ magnetic field may be distorted in the transverse x and y directions as well. The entire imaging volume V could be shimmed as a unit; however, imposing spatial uniformity on the large volume V may be difficult.

In the dynamic shimming approach illustrated in FIG. 4, the imaging volume V is divided up into four regions R₁, R₂, R₃, R₄ along the z-direction. Some regions exhibit more magnetic field variation than others. In the illustrated example, the regions R₃, R₄ have more magnetic field variation than the regions R₁, R₂. Each region R₁, R₂, R₃, R₄ is separately shimmed. That is, for each region, one or more shim currents are selected to substantially reduce non-uniformity of the main B₀ magnetic field in that region. Because the shimming is focused on smaller regions, more accurate shimming of each region can be performed. When the region R₁ is imaged, the shim currents selected to shim that region are employed. When the region R₂ is imaged, the shim currents selected to shim that region are employed. When the region R₃ is imaged, the shim currents selected to shim that region are employed. When the region R₄ is imaged, the shim currents selected to shim that region are employed.

FIG. 4 also diagrammatically plots the shimmed average main B₀ magnetic field |B(z)| averaged over each axial slice during imaging of that slice. The shimmed average main B₀ magnetic field in each region is substantially uniform, but exhibits a magnitude shift Δ|B₀|, which is not corrected in FIG. 4. The plots of the shimmed average main B₀ magnetic fields |B(z)| do not include optional compensation via the D.C. shim coil 82. Because each region R₁, R₂, R₃, R₄ is imaged using generally different selected shim currents, the size of the magnitude shift Δ|B₀| differs for each of the four regions. In the illustrated example, larger shim currents are applied during imaging of regions R₃, R₄ to compensate for the relatively large magnetic field non-uniformities in those regions prior to shimming; whereas, smaller shim currents are applied during imaging of regions R₁, R₁ which exhibit less field non-uniformity. Correspondingly, the shimmed main B₀ magnetic field in regions R₃, R₄ have larger magnitude shifts Δ|B₀| as compared with regions R₁, R₁. By using the magnitude shift processor 70 to compute the magnitude shift Δ|B₀| appropriate for each selected shim currents combination used to shim each respective region R₁, R₂, R₃, R₄, the changing magnitude shifts Δ|B₀| during the dynamically shimmed imaging is compensated.

While FIG. 4 illustrates four regions each including a plurality of slices, it will be appreciated that the dynamic shimming technique could be applied to other sub-volumes. For example, the dynamic shimming can be applied on a per-slice basis, in which shim currents are selected for each axial slice prior to imaging that slice.

In the embodiments heretofore described, shim currents are selected to reduce non-uniformity of the main B₀ magnetic field in an imaging region. Once the shim currents are selected, the magnitude shift Δ|B₀| produced by those selected shim currents is computed, and a correction for that computed magnitude shift Δ|B₀| is performed. The processes of selecting shim currents, computing the magnitude shift, and correcting are performed separately.

However, in other contemplated embodiments the processes of selecting shim currents, computing Δ|B₀|, and correcting are partially or wholly integrated together. For example, the shim currents can be determined by optimizing a figure of merit that includes a field uniformity component and a magnitude shift component Δ|B₀|. In this embodiment, the shim currents, including shim currents for the shim coils 60 and the D.C. shim coil 82, are simultaneously optimized by minimizing or maximizing the figure of merit, thus simultaneously performing the selecting of the shim currents and the computing of a correction of the magnitude shift Δ|B₀|.

Shimming affects volumes, and measurement of resonant frequency occurs over volumes, these volumes typically exhibiting spatial dependences. In one embodiment, shifts may be measured as an average over a predefined volume, for example, a 20 centimeter diameter spherical reference volume located at the center of the magnet. Other contemplated embodiments may include volume definitions such as (i) the extent of a planned subsequent imaging region, (ii) some fraction of the central region of a prescribed imaging volume, (iii) the physical extent of the subject to be imaged, perhaps limited within a larger predefined volume, (iv) a typical volume defined depending upon the human anatomy of interest, or (v) a region explicitly defined by the operator performing the MRI procedure. Numerous other definitions are possible.

Furthermore, the determination of the resonance frequency shift induced by an energized shim may incorporate the choice of the volume in any of several ways. Magnetic field shifts or shift coefficients may be defined for one or more predefined volumes. Shifts may be characterized with spatial dependences, such as by fitting polynomials or other spatial functions. Such polynomials may be spherical harmonics, or they may match the spatial distributions of the respective Maxwell terms of each shim coil, for example. Shifts or shift coefficients may be determined at each of several points in discretized maps, and stored as volume representations.

For purposes of illustration, a specific embodiment of computation of Maxwell terms is now further described. Utilizing a spherical harmonic expansion of the magnetic fields, the main magnet coils 20 can be utilized mainly to generate the zeroeth order spherical harmonic of B_{z}. The magnetic field gradient coils 30 can be utilized to generate or to correct the first order spherical harmonic terms of B_{z}. The magnetic shim coils 60 can be utilized to generate or to correct the second order spherical harmonic terms of B_{z}. These second order shims may be referred to, for example, as (x²−y²), xy, xz, yz, and z². The spatial dependence of each of these shims matches its name, except for the shim named z², which generates a field with the spatial dependence function of B_{z}=(z²−0.5*(x²+y²)). For each of these second order shims, the corresponding transverse field can be determined. The transverse fields Bₓ and B_{y} for each shim are constrained to a family of solutions, since the magnetic field must satisfy Maxwell's equations. Some freedom exists in the possible choice of the Bₓ and B_{y} functions.

In embodiments in which the shim coils are mechanically built on cylindrical surfaces, some symmetries can be incorporated into the solution. By imposing these symmetry constraints upon the candidate transverse fields Bₓ and B_{y} functions, the spatial dependence of each function is determined. For the (x²−y²) shim, the solution under these symmetry constraints is Bₓ=2xz and B_{y}=−2yz. For the xy shim, the solution under these symmetry constraints is Bₓ=2yz and B_{y}=2xz. For the z² shim, the solution under these symmetry constraints is Bₓ=−xz and B_{y}=−yz. Similar determinations can be performed for other second order shims.

In one embodiment, the total magnitude B shift is calculated for a shim current in any given shim coil by utilizing Equation (2) and integrating over a volume. The power series expansion of the square root function then yields coefficients for powers of the shim current. Only even powers will yield nonzero coefficients.

In another embodiment, the vector fields B=(Bₓ, B_{y}, B_{z}) for each shim are scaled proportional to the desired setting of the B_{z} component. The vectors for all the scaled shims are added. The magnitude of the summed vector is determined as a function of position x, y, and z. The resultant function is integrated over a volume of interest to give a final shifted B magnitude.

Extension of the previous embodiment for successively higher orders of shims is straightforward and is readily performed by those skilled in the art based on the foregoing description relating to second order shims.

It is to be appreciated that correction of the resonance frequency for deviations induced by shims may be useful regardless of the mechanism which initially causes the change of frequency. Thus, an observed frequency shift might be induced through other mechanisms, besides the Maxwell terms described above. Mechanical deflections due to static magnetic forces, or thermal effects associated with currents in resistive shim coils are other examples of mechanisms which might induced frequency changes. These and other mechanisms may exhibit the same basic functional dependence, even though they may vary in strength significantly from the predicted Maxwell terms effect. For example, energizing a shim of a coil of a specific spherical harmonic might induce slight geometric deflections in other magnetic structures, in turn inducing a frequency shift substantially proportional to the square of the shim current. Correction for such empirically observed magnetic field non-uniformities is readily performed using the foregoing calibration apparatuses and methods and straightforward variations thereof. Thus, the forgoing calibration apparatuses and methods are readily adapted to correct for empirically observed magnetic field non-uniformities observed or measured without identifying the underlying cause.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A magnetic resonance imaging method comprising:
determining a magnitude shift of a main B₀ magnetic field responsive to energizing one or more shim coils at selected shim currents;
energizing the one or more shim coils at the selected shim currents; and
performing a correction during the energizing to correct for the determined magnitude shift of the main B₀ magnetic field.

2. The magnetic resonance imaging method as set forth in claim 1, wherein the performing of a correction comprises:
adjusting a center frequency of radio frequency receiver and transmitter components to correspond to a magnetic resonance frequency at the B₀ magnetic field including the determined magnitude shift.

3. The magnetic resonance imaging method as set forth in claim 1, wherein the performing of a correction comprises:
energizing a D.C. shim coil at a D.C. shim current effective for canceling the determined magnitude shift of the main B₀ magnetic field.

4. The magnetic resonance imaging method as set forth in claim 1, wherein the performing of a correction comprises:
energizing one or more gradient coils to correct for one or more first order spherical harmonic terms of the determined magnitude shift of the main B₀ magnetic field.

5. The magnetic resonance imaging method as set forth in claim 1, wherein the determining a magnitude shift comprises:
computing one or more Maxwell terms of the magnetic field produced by energizing the one or more shim coils at selected shim currents; and
determining the magnitude shift of the main B₀, magnetic field based on the computed one or more Maxwell terms.

6. The magnetic resonance imaging method as set forth in claim 1, wherein the determining of a magnitude shift comprises:
for each of the one or more shim coils, determining one or more Maxwell term coefficients of the magnetic field produced by energizing that shim coil at the corresponding selected shim current;
for each of the one or more shim coils, determining a magnitude shift contribution of that coil by (i) obtaining one or more Maxwell terms corresponding to the one or more Maxwell term coefficients of that coil by multiplying each Maxwell term coefficient of that coil by the current raised to a corresponding even power and (ii) summing the Maxwell terms.

7. The magnetic resonance imaging method as set forth in claim 6, wherein the one or more shim coils includes a plurality of shim coils, and the determining of a magnitude shift further comprises:
additively combining the magnitude shift contributions of the plurality of coils to determine the magnitude shift of the main B₀ magnetic field.

8. The magnetic resonance imaging method as set forth in claim 6, wherein the determining of one or more Maxwell term coefficients comprises one of:
computing the Maxwell term coefficients based on a geometry of the coil, and
fitting a magnetic field produced by energizing the shim coil at a reference current to an expression including a sum of one or more Maxwell terms parameterized by the corresponding one or more Maxwell term coefficients, said Maxwell term coefficients being stored and subsequently recalled during the determining of a magnitude shift contribution of that coil.

9. The magnetic resonance imaging method as set forth in claim 1, wherein the one or more shim coils includes a plurality of shim coils, and the determining a magnitude shift comprises:
for each coil, determining a functional relationship between shim current and a shift contribution of that coil;
inputting the selected shim current into the functional relationship to determine a shift contribution corresponding to the selected shim current; and
combining the shift contributions corresponding to the selected shim currents of the plurality of coils to determine the magnitude shift.

10. The magnetic resonance imaging method as set forth in claim 9, wherein the combining of the shift contributions comprises:
determining the shift contribution for each shim coil in a vector form;
additively combining the shift contribution vectors for each shim coil; and
determining the magnitude of the vector shift contributions corresponding to the selected shim currents of the plurality of coils.

11. The magnetic resonance imaging method as set forth in claim 1, further comprising:
selecting the selected shim currents by optimizing a figure of merit including the shim currents of the shim coils and a shim current of a D.C. shim coil, wherein the performing of the correction includes energizing the D.C. shim coil at an optimized shim current obtained by the optimizing of the figure of merit.

12. The magnetic resonance imaging method as set forth in claim 1, further comprising:
dynamically selecting shim currents to dynamically shim the main B₀ magnetic field during magnetic resonance imaging, the determining of a magnitude shift, energizing, and performing of a correction being repeated for each selection of shim currents.

13. The magnetic resonance imaging method as set forth in claim 1, further comprising:
performing multi-slice magnetic resonance imaging of an imaging subject; and
for each slice, selecting shim currents of the one or more shim coils to dynamically shim the main B₀ magnetic field for that slice, the determining of a magnitude shift, energizing, and performing of a correction being performed for imaging of that slice.

14. The magnetic resonance imaging method as set forth in claim 1, further comprising:
dividing a region to be imaged into a plurality of imaging regions;
for each imaging region, determining selected shim currents effective for shimming the main B₀ magnetic field in that imaging region, the determining of the magnitude shift responsive to energizing one or more shim coils at selected shim currents being separately performed for each imaging region for the selected shim currents effective for shimming the main B₀ magnetic field in that imaging region; and
acquiring imaging data for each imaging region, wherein:
(i) the energizing is performed as part of the imaging and uses the selected shim currents effective for shimming the main B₀ magnetic field in that imaging region being imaged, and
(ii) the performing of a correction is performed with respect to the magnitude shift determined for that region being imaged.

15. A magnetic resonance imaging apparatus comprising:
a means for generating a main B₀ magnetic field;
one or more shim coils for shimming the main B₀ magnetic field;
a means for determining a magnitude shift of the main B₀ magnetic field responsive to energizing the one or more shim coils at selected shim currents;
a means for energizing the one or more shim coils at the selected shim currents; and
a means for performing a correction during the energizing to correct for determined magnitude shift of the main B₀ magnetic field.

16. The magnetic resonance imaging apparatus as set forth in claim 15, wherein the means for determining the magnitude shift includes a processor which performs a process including:
determining one or more Maxwell terms coefficients for each shim coil;
computing a magnitude shift of the main B₀ magnetic field produced by each coil based on a shim coil function having functional parameters including the one or more Maxwell term coefficients for that coil and the selected shim current for that coil; and
combining the magnitude shift of the main B₀ magnetic field produced by each coil.

17. The magnetic resonance imaging apparatus as set forth in claim 15, wherein the correction performing means includes at least one of:
a means for activating a zero order shim coil to adjust a magnitude of the main B₀ magnetic field; and
a means for shifting a resonance excitation frequency.

18. A magnetic resonance imaging scanner comprising:
a main magnet generating a main B₀ magnetic field;
one or more shim coils selectively shimming the main B₀ magnetic field at selected shim currents; and
a processor executing a process including determining a magnitude shift of the main B₀ magnetic field responsive to the selective shimming.

19. The magnetic resonance imaging scanner as set forth in claim 18, further comprising:
a zero order shim coil selectively energized to counteract the determined magnitude shift of the main B₀ magnetic field responsive to the selective shimming.

20. The magnetic resonance imaging scanner as set forth in claim 18, further comprising:
a tunable radio frequency transceiver generating a radio frequency signal and detecting magnetic resonance signals produced responsive to the generated radio frequency signal;
wherein the process executed by the processor further includes computing a magnetic resonance frequency corresponding to the main B₀ magnetic field including the determined magnitude shift, the tunable radio frequency transceiver being tuned to the computed magnetic resonance frequency.
